(19) United States
(12) Patent Application Publication
(10) Pub. No.: US 2026/0228386 A1
(43) Pub. Date: Aug. 6, 2026

(54) TRAFFIC FLOW PREDICTION DEVICE

(71) Applicant: TOYOTA JIDOSHA KABUSHIKI KAISHA, Toyota-shi (JP)

(72) Inventors: Masaaki INOUE, Tokyo (JP); Takeyuki Sasai, Tokyo (JP); Jiawei Yong, Tokyo (JP); Shintaro Fukushima, Tokyo (JP)

(73) Assignee: TOYOTA JIDOSHA KABUSHIKI KAISHA, Toyota-shi (JP)

(21) Appl. No.: 19/427,170

(22) Filed: Dec. 19, 2025

(30) Foreign Application Priority Data
Jan. 24, 2025 (JP) 2025-010949

(51) Int. Cl. G06F 30/20; G08G 1/01

(52) U.S. Cl. CPC G06F 30/20; G08G 1/0112; G08G 1/0129

(57) ABSTRACT

A traffic flow prediction device acquires data of a moving object at a past date and time and at a current point in time, determines a resolution of data newly transmitted from the moving object by using an analysis result of the data or a prediction result of a traffic flow based on the data, and predicts a future traffic flow by using the data transmitted from the moving object at the resolution.

### CROSS-REFERENCE TO RELATED APPLICATION

This application claims priority to Japanese Patent Application No. 2025-010949 filed on January 24, 2025. The disclosure of the above-identified application, including the specification, drawings, and claims, is incorporated by reference herein in its entirety.

### BACKGROUND

### Technical Field

The present disclosure relates to a traffic flow prediction device.

### Description of Related Art

In recent years, a technology for analyzing a flow of a moving object has been developed. For example, Japanese Unexamined Patent Application Publication No. 2023-26294 (JP 2023-26294 A) discloses a pedestrian flow analysis system that can analyze pedestrian flow data while suppressing an increase in a processing load for analyzing the pedestrian flow data.

### SUMMARY

However, in the technology described in JP 2023-26294 A, the processing of suppressing a high load is merely a cleansing process (only a process of thinning out position information indicating the same position) based on a uniform GPS-based criterion. The processing does not reflect a trade-off related to an estimation accuracy based on data characteristics estimated from past data.

An object of the present disclosure made in view of such circumstances is to be able to reduce a processing load while suppressing a decrease in prediction accuracy based on data characteristics estimated from past data.

A traffic flow prediction device according to an embodiment of the present disclosure is configured to acquire data of a moving object at a past date and time and at a current point in time, determine a resolution of data to be newly transmitted from the moving object by using an analysis result of the data or a prediction result of a traffic flow based on the data, and predict a future traffic flow by using the data newly transmitted from the moving object at the resolution.

According to the present disclosure, it is possible to reduce a processing load while suppressing a decrease in prediction accuracy based on data characteristics estimated from past data.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a diagram showing a configuration of a traffic flow prediction system according to an embodiment;

FIG. 2 is a flowchart showing a processing procedure of a traffic flow prediction device according to an embodiment; and

FIG. 3 is an image diagram showing a difference in resolution of data.

### DETAILED DESCRIPTION OF EMBODIMENTS

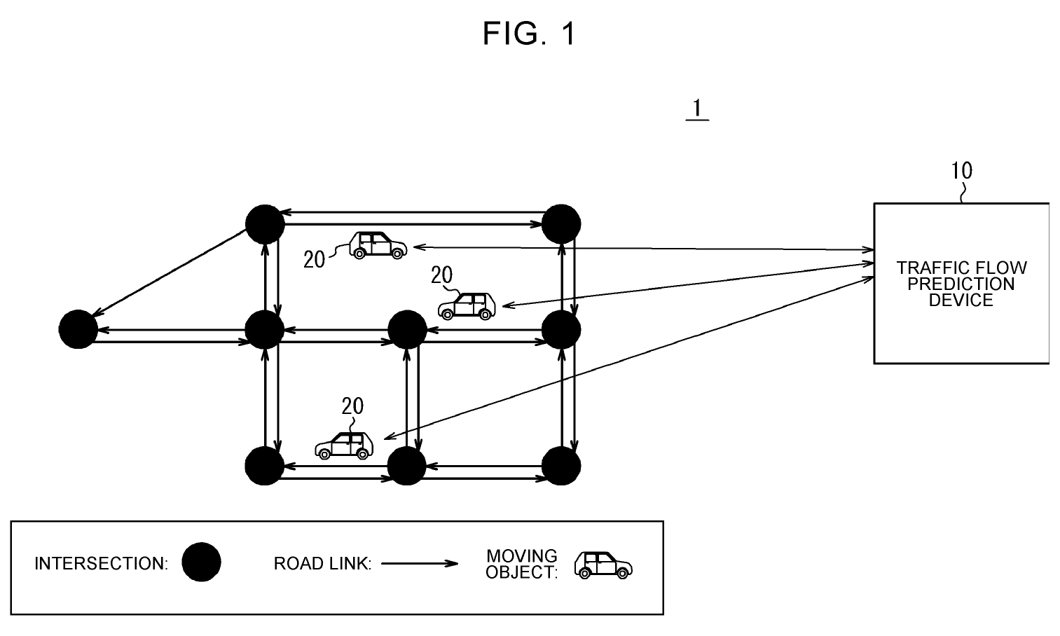

A traffic flow prediction system 1 according to an embodiment shown in FIG. 1 includes one or more moving objects (vehicles, pedestrians, and the like) 20 and a traffic flow prediction device (data control device) 10. The traffic flow prediction device 10 may be a database server. The traffic flow prediction device 10 is installed in a center. The vehicle 20 and the traffic flow prediction device 10 are communicably connected to each other via a network.

The moving object 20 includes one or more sensors and a communication unit (communication interface) for communicating with the traffic flow prediction device 10. Each moving object 20 transmits traveling data or the like (hereinafter, simply referred to as "data") detected by the sensor to the traffic flow prediction device 10. The "data" includes, for example, a vehicle identification number, GPS position information, a time, a vehicle speed, an acceleration, a driving operation (accelerator, brake, or the like), and attribute information of a driver or a passenger.

The traffic flow prediction system 1 acquires data at a past date and time and at a current point in time (real time) from the moving object 20 in a road traffic network as a moving data log. Then, the spatiotemporal characteristics of the road traffic network obtained from the moving data log, a prediction result (execution result of a prediction task) of a traffic flow (such as traffic volume, passing speed, bias of the attribute of the moving object 20), and the like are fed back. The traffic flow prediction system 1 adaptively (dynamically) reduces the resolution of the data in consideration of a balance between the amount of data used for the prediction task of the traffic flow and the prediction accuracy. Therefore, the traffic flow prediction system 1 can reduce the amount of data newly acquired from the moving object 20 while suppressing a decrease in prediction accuracy, and can reduce a communication load and a calculation load. The traffic flow prediction system 1 can adaptively determine the resolution (a sampling cycle of the data to be acquired, a group of moving objects to be acquired, and the like) for each situation such as a target road link and a time slot. In addition, the processing of reducing the resolution can be executed as distributed processing on an edge side (side of the moving object 20) or as centralized processing on a center side (side of the traffic flow prediction device 10).

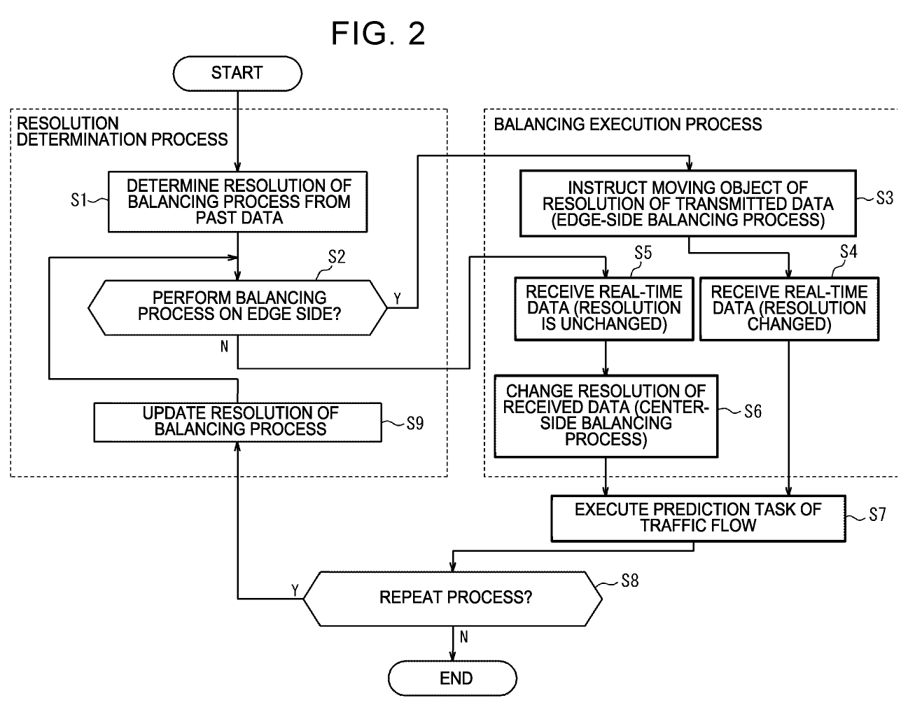

A processing procedure example of the traffic flow prediction device 10 will be described with reference to FIG. 2.

In S1, the traffic flow prediction device 10 determines the resolution for performing the balancing process using the past data. The traffic flow prediction device 10 dynamically determines a specification of the resolution of the data newly transmitted from the moving object 20 by using an analysis result based on the data of the past moving object 20 or the prediction result of the traffic flow. For example, the traffic flow prediction device 10 may analyze the data of the past moving object 20 for each road link and each time slot on the road network, and determine the reduced resolution based on spatiotemporal regularity of the stability of the traffic flow. In addition, the traffic flow prediction device 10 may determine the reduced resolution within a range in which a desired prediction accuracy can be maintained, which is empirically obtained from a record of the prediction accuracy based on the prediction result of the traffic flow.

In S2, the traffic flow prediction device 10 determines whether to perform the balancing process on the edge side.

In S3, in a case in which the balancing process is performed on the edge side (Yes in S2), the traffic flow prediction device 10 instructs the moving object 20 of the resolution of the data newly transmitted from each moving object 20 (resolution determined in S1 or S9) (edge-side balancing process).

In S4, the traffic flow prediction device 10 receives the data at the resolution determined in S3 from the moving object 20 in real time.

In S5, in a case in which the balancing process is not performed on the edge side (No in S2), the traffic flow prediction device 10 receives the data at a default resolution from the moving object 20 in real time.

In S6, the traffic flow prediction device 10 changes the resolution of the data received in S5 in accordance with the specification of the resolution determined in S1 to reduce the amount of data (center-side balancing process). In a case in which the edge-side balancing process in S3 is not performed, the traffic flow prediction device 10 performs the center-side balancing process in S6.

In S7, the traffic flow prediction device 10 predicts the future traffic flow by using, as an input, the data that has been subjected to the balancing process in S3 or S6 and that is transmitted from each moving object 20 at a designated resolution. In the first embodiment described below, the expansion estimation of the total traffic volume is performed, and in a second embodiment, traffic statistical information is predicted.

In S8, the traffic flow prediction device 10 determines whether to perform the repeating process. In a case in which the confidence level exceeds a target value or the like, that is, in a case in which the repeating condition is not satisfied (No in S8), the process ends.

In S9, in a case in which the repeating process is performed (Yes in S8), the specification of the resolution of the balancing process is updated in accordance with the confidence level of the result of the traffic flow predicted in S7, and the process returns to the process of S2.

### First Embodiment - Expansion Estimation of Total Traffic Volume -

The expansion estimation of the total traffic volume is a process of estimating the total traffic volume of the road traffic network based on the data acquired from only a part of the connected car group (for example, a specific vehicle type group, a vehicle group of a specific manufacturer, and the like). It is known that the traffic volume of the vehicle group obtained from the position information, the time information, and the like included in the data is one of the important explanatory variables (for example, see the following reference). [Reference] Yong, J., Wakabayashi, Y., Okayasu, A., Miki, R., Sasai, T., Inoue, M., & Fukushima, S. (2022). Estimating Total Traffic Volume with Statistical Modeling Approach. In 2022 IEEE 25th International Conference on Intelligent Transportation Systems (ITSC), pp. 304-309, IEEE.

In S1, the traffic flow prediction device 10 determines a combination of the situation and the granularity using the past data based on a criterion selected in advance. That is, the traffic flow prediction device 10 reduces the resolution of the data by coarsening the granularity as much as possible for each situation, to make the data easier to handle quantitatively.

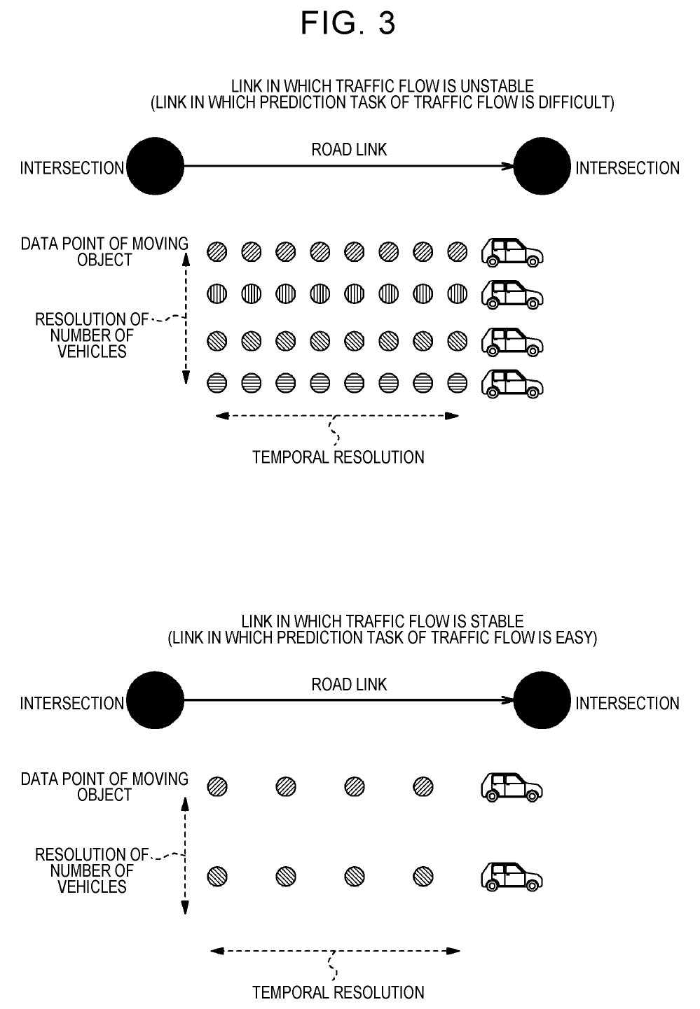

FIG. 3 is an image diagram showing the process of S1. In a link in which the traffic flow is unstable, a resolution close to the raw data is used, and in a link in which the traffic flow is stable, the resolution is coarsened from the raw data (the reduction rate is increased). The specification of the resolution is composed of a combination of the situation and the granularity, and is determined to conform to the criterion. Hereinafter, details of the setting of the criterion, the situation, and the granularity will be described.

The "criterion" for determining the situation and the granularity related to the resolution is determined according to the characteristics of the past data. Examples of the determination criterion used for reducing the amount of data will be described below.

(1) Spatiotemporal regularity related to stability of past data is used:

For example, the determination criteria include traffic volume (a location/time slot in which the dispersion of the traffic volume is small, a location in which the periodicity of the time slot/day of the week is strong), a tendency in the occurrence of a sudden event (a location/time in which a sudden event such as an accident, congestion, and a traffic restriction is unlikely to occur), a bias in the attribute of the moving object 20 (a location in which the penetration rate of the vehicle group to be acquired is high), and the like.

(2) Record of prediction accuracy of expansion estimation of past total traffic volume is used:

For example, a location/time in which the prediction accuracy of the expansion estimation is high even with a small amount of data empirically obtained from the record is set as the determination criterion.

The "situation" for setting the granularity can be determined by a broad classification into two types, temporal and spatial.

(i) Temporal situation:

For example, the granularity is determined for each unit of time slot/day of the week/season.

(ii) Spatial situation:

For example, the granularity is determined for each unit of region/road.

The specification of the "granularity" for the data to be newly acquired can be set by being largely classified into two types of the granularity of time and the granularity of the sample for each situation.

(a) Granularity of time (sampling cycle):

For example, the sampling cycle is changed for each situation.

(b) Granularity of sample:

For example, the proportion of the vehicle group to be sampled among the vehicles from which the data can be acquired is changed for each situation. For example, the number of data items (vehicle speed, fuel consumption, and the like) to be sampled is changed for each situation.

The traffic flow prediction device 10 combines, for example, the above (2)-(i)-(a) to perform resolution reduction of the sampling cycle of the data of all vehicles for the past 24 hours on the expressway in Tokyo that has been acquired, in a simulated manner. The traffic flow prediction device 10 calculates, by simulation, the threshold value of the sampling cycle at which the average error of the expansion estimation is less than a predetermined value (for example, 10%) for each time in units of a predetermined time (for example, 1 hour), and determines the resolution of the data to be newly transmitted as the threshold value.

In addition, the traffic flow prediction device 10 combines, for example, the above (1)-(ii)-(b) to determine the thinning-out rate of the vehicle group to be instructed to acquire the data according to the penetration rate (coverage rate) of the vehicle for each region for the vehicle group to be acquired. In a case in which it is sufficient to ascertain 25% of the passing vehicles, the data transmission is instructed to 50% of the vehicles in a region in which the penetration rate of the vehicle to be acquired is 50% on the road. In a region in which the penetration rate of the vehicle to be acquired is 25% on the road, the data transmission is instructed to 100% of the vehicles.

In S3, the traffic flow prediction device 10 transmits the specification of the resolution determined in S1 to the vehicle for acquiring the data on the road traffic network. Since the target vehicle transmits the data at the resolution according to the specification in the subsequent data transmission, the data is reduced in resolution, and the communication load is reduced.

In S4 and S5, the traffic flow prediction device 10 acquires the data from the vehicle group for acquiring the data in real time. In S4, the traffic flow prediction device 10 acquires the data at a resolution for each situation, such as acquiring the data at 300-millisecond intervals on the road A on a weekday, 400-millisecond intervals on the road A on a holiday, 200-millisecond intervals on the road B on a weekday, and 500-millisecond intervals on the road B on a holiday. In S5, the traffic flow prediction device 10 acquires the data at a default setting, such as acquiring the data at 500-millisecond intervals at any time on any road.

In S6, the traffic flow prediction device 10 performs a process of reducing the resolution of the data received in S5 according to the specification of the resolution determined in S1.

In S7, the traffic flow prediction device 10 executes the expansion estimation of the total traffic volume by using the data after the balancing process. For example, the traffic flow prediction device 10 trains the parameters of the regression model (linear regression model, mixed-effects model, and the like) using the past data and then inputs the newly acquired real-time data and outputs the prediction result. For example, the response variable is set to the total traffic volume per hour for each road, and the explanatory variable is set to the traffic volume of the vehicle for acquiring the data, the average vehicle speed, the standard of the target road, the number of lanes, and the category of the time slot/day of the week per hour for each road. The feature amount may be directly obtained from the data (traffic volume of the vehicle group for each road, time slot, day of the week, and presence or absence of a holiday, or the like). In addition, the feature amount may be obtained in combination with information from an external database (road features (road standard, number of lanes, and the like) of the road on which the vehicle is located, a weather state, and the like).

In S8, the traffic flow prediction device 10 checks a goodness of fit of the data after the balancing process to the traffic engineering model (QV curve and the like) calculated in advance from the past data and calculates the confidence level of the data for each situation of the resolution. The traffic flow prediction device 10 sets the repeat determination to Yes only in a case in which the confidence level of the obtained data is less than a predetermined threshold value and the acquired data can be increased in resolution (the set value of the current resolution specification is less than the upper limit value of the system).

In S9, the traffic flow prediction device 10 updates the specification of the granularity of the situation of the resolution at which it is determined that further data acquisition is necessary according to the confidence level of the repeat determination by the same method as in S1.

### Second Embodiment - Prediction of Traffic Statistical Information -

The data of the moving object 20 used for the prediction task related to statistics such as the average speed and the average travel time (required time) is subjected to the balancing process for the traffic statistical information (statistical information related to the smoothness of the traffic flow) for each road in the road traffic network. Hereinafter, different points from the first embodiment will be indicated in angle brackets (< >).

In S1, the specification of the resolution for the balancing process is determined by combining the situation and the granularity using the past data based on the <determination> criterion selected in advance. The traffic flow prediction device 10 performs resolution reduction of the sampling cycle of the data of all vehicles for the past 24 hours on the expressway in Tokyo that has been acquired, in a simulated manner. The traffic flow prediction device 10 calculates, by simulation, the threshold value of the sampling cycle at which the average error of <average speed estimation or average travel time> is less than a predetermined value (for example, 10%) for each time in units of a predetermined time (for example, 1 hour), and determines the resolution of the data to be newly transmitted.

In S7, the traffic flow prediction device 10 executes <estimation of traffic statistical information> by using the data after the balancing process. For example, the traffic flow prediction device 10 trains the parameters of the regression model using the past data and then inputs the newly acquired real-time data to output the prediction result. For example, the response variable is set to <average vehicle speed> per hour for each road, and the explanatory variable is set to <average vehicle speed, traffic volume> of the vehicle for acquiring the data per hour for each road, the standard of the target road, the number of lanes, and the category of the time slot/day of the week. The feature amount may be directly obtained from the data (the <average vehicle speed> of the vehicle group for each road, time slot, day of the week, and presence or absence of a holiday, or the like) or may be obtained in combination with information from an external database.

In the above-described embodiment, in a case in which the moving object 20 is particularly a "vehicle", in S1, the traffic flow prediction device 10 may determine the resolution in consideration of the characteristics of the vehicle data including the driving characteristics and the vehicle characteristics, and the characteristics of the road traffic including the road characteristics and the traffic characteristics. The "driving characteristics" are characteristics estimated from the past data as a driver model of the bias of the driving operation (driving proficiency, the number of detours/rests, and the like). The "vehicle characteristics" are traveling performance of the vehicle estimated from the past data such as the vehicle type, the total traveling distance, and the traveling fuel efficiency. The "road characteristics" are information (number of lanes, width, curvature, and the like) on a road link related to the smoothness of the traffic flow. The "traffic characteristics" are traffic restriction information (speed limit, restriction sign, and the like) related to the road traffic law, traffic information (congestion/accident information provided by a service provider, and the like), and the like. In addition, the traffic flow prediction device 10 may use the goodness of fit using the above-described characteristics to determine whether to perform the repeating process of S8.

Since the data of the moving object 20 is spatiotemporally continuous, in a case in which the data is continuously sampled at a small time or a large sample in priority to the resolution of the data, the amount of data becomes enormous, and the communication load and the computational load of the task processing become unrealistic. In this regard, the traffic flow prediction device 10 determines the resolution of the data newly transmitted from the moving object 20 by using the analysis result of the data acquired from the moving object 20 or the prediction result of the traffic flow and predicts the future traffic flow by using the data newly transmitted at the resolution. Therefore, the traffic flow prediction device 10 can reduce the processing load while suppressing the decrease in prediction accuracy.

In order to function as the traffic flow prediction device 10 described above, a computer that can execute a program command can also be used. The program may be recorded on a computer-readable non-transitory recording medium.

The above-described embodiment has been described as a representative example, but it is clear to those skilled in the art that changes and substitutions can be made within the gist and scope of the present disclosure. For example, a plurality of steps described in the flowchart of the embodiment can be integrated into one step, or one step can be divided into the steps.

What is claimed is:

1. A traffic flow prediction device configured to
acquire data of a moving object at a past date and time and at a current point in time,
determine a resolution of data to be newly transmitted from the moving object by using an analysis result of the data or a prediction result of a traffic flow based on the data, and
predict a future traffic flow by using the data newly transmitted from the moving object at the resolution.

2. The traffic flow prediction device according to claim 1, wherein:
prediction of the traffic flow is expansion estimation of a total traffic volume; and
the traffic flow prediction device is configured to perform, in a simulated manner, resolution reduction of the data that is acquired, calculate, in a predetermined time unit, a threshold value of a resolution at which an average error of the prediction result of the traffic flow is less than a predetermined value, and determine the threshold value to be the resolution of the data to be newly transmitted.

3. The traffic flow prediction device according to claim 1, wherein:
prediction of the traffic flow is prediction of traffic statistical information; and
the traffic flow prediction device is configured to perform, in a simulated manner, resolution reduction of the data that is acquired, calculate, in a predetermined time unit, a threshold value of a resolution at which an average error of average speed estimation or average travel time is less than a predetermined value, and determine the threshold value to be the resolution of the data to be newly transmitted.
